(19) United States
(12) Patent Application Publication
(10) Pub. No.: US 2026/0215314 A1
(43) Pub. Date: Jul. 23, 2026

(54) SEMICONDUCTOR STRUCTURE AND METHOD OF FORMING THE SAME

(71) Applicant: Yangtze Memory Technologies Co., Ltd., Wuhan (CN)

(72) Inventors: Jun CHEN, Wuhan (CN); Ziqun HUA, Wuhan (CN); Siping HU, Wuhan (CN); Jiawen WANG, Wuhan (CN); Tao WANG, Wuhan (CN); Jifeng ZHU, Wuhan (CN); Taotao DING, Wuhan (CN); Xinsheng WANG, Wuhan (CN); Hongbin ZHU, Wuhan (CN); Weihua CHENG, Wuhan (CN); Shining YANG, Wuhan (CN)

(21) Appl. No.: 19/569,860

(22) Filed: Mar. 17, 2026

Related U.S. Application Data
(63) Continuation of application No. 17/367,431, filed on Jul. 5, 2021.
Application No. 17/367,431 is a division of application No. 16/378,517, filed on Apr. 8, 2019, now abandoned.
Application No. 16/378,517 is a continuation of application No. PCT/CN2018/093692, filed on Jun. 29, 2018.

(51) Int. Cl. H10W 72/00; H10W 72/30; H10W 80/00; H10W 90/00

(52) U.S. Cl. CPC H10W 72/019; H10W 72/013; H10W 72/322; H10W 72/342; H10W 72/353; H10W 80/312; H10W 80/327; H10W 80/701; H10W 90/732; H10W 90/792

(57) ABSTRACT

The present invention relates to a semiconductor structure and method of forming the same. The semiconductor structure includes a first substrate, a first adhesive/bonding stack on the surface of first substrate, wherein the first adhesive/bonding stack includes at least one first adhesive layer and at least one first bonding layer. The material of first bonding layer includes dielectrics such as silicon, nitrogen and carbon, the material of first adhesive layer includes dielectrics such as silicon and nitrogen, and the first adhesive/bonding stack of semiconductor structure is provided with higher bonding force in bonding process.

### CROSS REFERENCE TO RELATED APPLICATIONS

This application is a continuation application of U.S. patent application Ser. No. 17/367,431 filed on Jul. 5, 2021, which is a divisional application of Application Ser. No. 16/378,517, filed on Apr. 8, 2019, and entitled “SEMICONDUCTOR STRUCTURE AND METHOD OF FORMING THE SAME”, which is a continuation application of International Patent Application No. PCT/CN2018/093692, filed on Jun. 29, 2018, which is incorporated herein by reference.

### BACKGROUND OF THE INVENTION

### FIELD OF THE INVENTION

The present invention generally relates to semiconductor technology, and more specifically, to a semiconductor structure and method of forming the same.

### Description of the Prior Art

In the technology platform of a three-dimensional (3D) chip, at least two wafers with semiconductor devices formed thereon are usually bonded together through wafer bonding technology to increase the integration of IC. In current wafer bonding technology, silicon oxide based film or silicon nitride based film are usually used as a bonding film at the wafer bonding interface.

In prior art, silicon oxide film and silicon nitride film are used as a bonding film. However, the bonding strength of these kinds of film is not sufficient, so that defects easily happen in the process to affect the yield of product.

Furthermore, metal interconnections will be formed in the bonding film. In the process of hybrid bonding, the metal interconnections may easily cause diffusion phenomenon at the bonding interface to affect the performance of product.

Accordingly, how to increase the quality of wafer bonding is currently an urgent topic in the development of 3D chip.

### SUMMARY OF THE INVENTION

The technical matter solved by the present invention is to provide a semiconductor structure and a method of forming the same.

The present invention provides a semiconductor structure, wherein the semiconductor structure includes a first substrate and a first adhesive/bonding stack on the surface of first substrate. The first adhesive/bonding stack includes at least one first adhesive layer and at least one first bonding layer, and the materials of first adhesive layer and first bonding layer are different, the material of first bonding layer includes dielectric materials like silicon (Si), nitrogen (N) and carbon (C), and the material of first adhesive layer includes dielectric material like silicon and nitrogen.

Optionally, the surface of first substrate contacts the first adhesive layer, and a surface of first adhesive/bonding stack is a surface of the first bonding layer.

Optionally, the atomic concentration of carbon in the first bonding layer is larger than 0% and smaller than 50%.

Optionally, the atomic concentration of carbon in the first bonding layer is uniform, or the atomic concentration of carbon in the first bonding layer gradually changes along with the increase of thickness of the first bonding layer.

Optionally, the first adhesive layer further includes carbon, and the atomic concentration of carbon in the first adhesive layer is uniform, or the atomic concentration of carbon in the first adhesive layer gradually changes along with the increase of thickness of the first adhesive layer.

Optionally, the atomic concentration of carbon in the first adhesive/bonding stack gradually changes in a direction of thickness of the first adhesive/bonding stack.

Optionally, the compactness of each layer in the first adhesive/bonding stack gradually changes in a direction of thickness of the first adhesive/bonding stack.

Optionally, the thickness of first bonding layer is larger than 100 Å, and the thickness of first adhesive layer is larger than 10 Å.

Optionally, the semiconductor structure further includes a second substrate, wherein a second adhesive/bonding stack is formed on the surface of second substrate, and the surfaces of second adhesive/bonding stack and first adhesive/bonding stack are correspondingly bonded together.

Optionally, the second adhesive/bonding stack and the first adhesive/bonding stack have the same material and structure.

Optionally, the semiconductor structure further includes a first bonding pad penetrating through the first adhesive/bonding stack and a second bonding pad penetrating through the second adhesive/bonding stack, wherein the first bonding pad and the second bonding pad are correspondingly bonded and connected together.

The technical solution by the present invention further provides a method of forming a semiconductor structure, which includes the steps of providing a first substrate and forming a first adhesive/bonding stack on the surface of first substrate, wherein the first adhesive/bonding stack includes at least one first bonding layer and at least one first adhesive layer, and the materials of first adhesive layer and the first bonding layer are different. The material of first bonding layer includes dielectric material like silicon (Si), nitrogen (N) and carbon (C), and the material of first adhesive layer includes dielectric material like Si and N.

Optionally, the atomic concentration of carbon in the first bonding layer is larger than 0% and smaller than 50%.

Optionally, the atomic concentration of carbon in the first bonding layer is uniform, or the atomic concentration of carbon in the first bonding layer gradually changes along with the thickness of first bonding layer.

Optionally, the first adhesive layer further includes carbon, and the atomic concentration of carbon in the first adhesive layer is uniform, or the atomic concentration of carbon in the first adhesive layer gradually changes along with the increase of thickness of the first adhesive layer.

Optionally, the atomic concentration of carbon in the first adhesive/bonding stack gradually changes in a direction of thickness of the first adhesive/bonding stack, or the compactness of each layer in the first adhesive/bonding stack gradually changes in a direction of thickness of the first adhesive/bonding stack.

Optionally, the thickness of first bonding layer is larger than 100 Å, and the thickness of first adhesive layer is larger than 10 Å.

Optionally, the semiconductor structure forming method further includes the steps of providing a second substrate, forming a second adhesive/bonding stack on the surface of second substrate, and correspondingly bonding the surfaces of second adhesive/bonding stack and the surface of first adhesive/bonding stack.

Optionally, the second adhesive/bonding stack and the first adhesive/bonding stack have the same material and structure.

Optionally, the semiconductor structure forming method further includes the steps of forming a first bonding pad penetrating through the first adhesive/bonding stack, forming a second bonding pad penetrating through the second adhesive/bonding stack, and correspondingly bonding the first bonding pad and the second bonding pad when correspondingly bonding the surface of second adhesive/bonding stack and the surface of first adhesive/bonding stack.

The semiconductor structure of present invention includes a first substrate and a first adhesive/bonding stack on the surface of first substrate, wherein the first adhesive/bonding stack is a composite bonding layer and includes at least one first adhesive layer and at least one first bonding layer. The first adhesive/bonding stack and the surface of first substrate may provide higher adhesive force. The bonding interface therebetween would also have higher bonding force after bonding and may prevent the diffusion of metal materials at the bonding interface, thereby improving the performance of semiconductor structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 4 are schematic figures sequentially illustrating a forming process of a semiconductor structure in accordance with an embodiment of the present invention;

FIG. 5 is a schematic figure of a semiconductor structure in accordance with an embodiment of the present invention; and

FIG. 6 is a schematic figure of a semiconductor structure in accordance with an embodiment of the present invention.

### DETAILED DESCRIPTION

In the following detailed description of the invention, reference is made to the accompanying drawings, which form a part hereof, and in which is shown, by way of illustration, specific embodiments in which the semiconductor structure and the method of forming the same of the invention may be practiced.

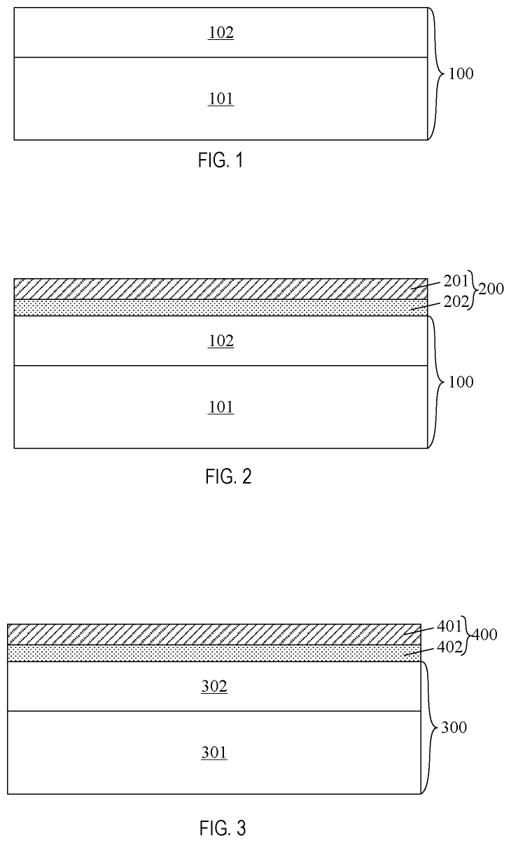

Please refer to FIG. 1 to FIG. 4, which are schematic figures sequentially illustrating a process of forming a semiconductor structure in accordance with an embodiment of the present invention.

Please refer to FIG. 1. First provide a first substrate 100.

The first substrate 100 includes a first semiconductor substrate 101, a first device layer 102 formed on the surface of first semiconductor substrate 101.

The first semiconductor substrate 101 may be single-crystal silicon substrate, germanium (Ge) substrate, silicon-germanium (SiGe) substrate, silicon-on-insulator (SOI) substrate or germanium-on-insulator (GOI) substrate, etc. Suitable first semiconductor substrate 101 may be selected depending on actual requirement of the device, but not limited thereto. In preferred embodiment, the first semiconductor substrate 101 is a single-crystal silicon wafer.

The first device layer 102 includes semiconductor devices formed on first semiconductor substrate 101, metal interconnections connecting the semiconductor devices, dielectric layers covering the semiconductor devices and the metal interconnections, etc. The first device layer 102 may be multilayer or single-layer structure. In the embodiment, the first device layer 102 includes dielectric layers and 3D NAND structure formed in the dielectric layers.

Please refer to FIG. 2. A first adhesive/bonding stack 200 is formed on the surface of first substrate 100. The first adhesive/bonding stack 200 includes at least one stacked first bonding layer 201 and at least one stacked first adhesive layer 202. The surface of first adhesive/bonding stack opposite to the first substrate is bonding surface.

In the embodiment, the first adhesive/bonding stack 200 includes the first adhesive layer 202 on the surface of first substrate 100 and the first bonding layer 201 on the surface of first adhesive layer 202.

The materials of first bonding layer 201 and first adhesive layer 202 are different. More specifically, the first bonding layer 201 and first adhesive layer 202 may include the same elements, but with different element concentration, or the first bonding layer 201 and first adhesive layer 202 may include different elements. The first adhesive layer 202 and the first bonding layer 201 may be sequentially formed by using individual chemical vapor deposition (CVD) processes. In the embodiment, the first adhesive layer 202 and the first bonding layer 201 is formed by using plasma enhanced chemical vapor deposition (PECVD) processes.

The material of first bonding layer 201 includes the dielectric materials like silicon (Si), nitrogen (N) and carbon (C). The material of first adhesive layer 202 includes the dielectric materials like silicon (Si) and nitrogen (N). The first bonding layer 201 and the first bonding layer 202 may be further doped with at least one element of oxygen (O), hydrogen (H), phosphorus (P) and fluorine (F), depending on the reagent gas using in the PECVD process and the requirement of products. For example, the material of first bonding layer 201 may be doped silicon nitride, doped silicon oxynitride and doped silicon carbonitride, etc. The material of first adhesive layer 202 may be silicon nitride and silicon oxynitride, etc.

In an embodiment, the reagent gas using in the PECVD process of forming the first adhesive layer 202 includes SiH4 and NH3, with the flow ratio of SiH4 to NH3 larger than 0.5 under a radio frequency power larger than 300 W. The reagent gas using in the PECVD process of forming the first bonding layer 201 includes one of trimethylsilane or tetramethylsilane and NH3, with the flow ratio of trimethylsilane or tetramethylsilane to NH3 larger than 0.5 under a radio frequency power larger than 300 W.

In another embodiment, the first adhesive layer 202 and the bonding layer 201 may be formed by performing a treatment to the dielectric materials. For example, after a silicon oxide film is formed on the surface of first substrate 100, performing a nitrogen doping process to the silicon oxide film to form the first adhesive layer 202. A silicon nitride film is then formed on the surface of first adhesive layer 202 and is doped with carbon to form a first bonding layer 201. Suitable material and treatment for the dielectric film may be selected depending on the materials of first adhesive layer 202 and first bonding layer 201 to be formed.

The element concentration in the first bonding layer 201 and the first adhesive layer 202 may be adjusted by controlling the process parameters of forming the first bonding layer 201 and the first adhesive layer 202, so that the bonding force between the first substrate 100 and the first adhesive layer 202 and between the first adhesive layer 202 and the first bonding layer 201 and the dielectric constant of first adhesive/bonding stack 200 may be adjusted.

The first bonding layer 201 is on the top of first adhesive/bonding stack 200. The carbon in first bonding layer 201 may efficiently increase the bonding force between the first bonding layer 201 and other bonding layers in a bonding process. The higher the carbon concentration, the stronger the bonding force to another bonding layer resulted in bonding process. In an embodiment, the atomic concentration of carbon in the first bonding layer is larger than 0% and smaller than 50%.

The first adhesive layer 202 has higher silicon atomic concentration, thereby increasing the compactness of first adhesive layer 202 and the bonding force to the first bonding layer 201 and the first device layer 102. In an embodiment, the atomic concentration of silicon in the first adhesive layer 202 is larger than 20%. The first adhesive layer 202 further includes carbon, and its carbon atomic concentration is smaller than the carbon atomic concentration in the first bonding layer 201. In comparison to the method that forming the first bonding layer 201 directly on the surface of first device layer 102, the adhesive force between the first adhesive/bonding stack 200 and the first device layer 102 in the embodiment may be effectively improved since the bonding force between the first adhesive layer 202 and the first device layer 102 is stronger.

Since the bonding force between different materials is related to material compositions at both sides of the bonding interface, the bonding force would get stronger if the material compositions are similar. In order to further increase the bonding force between the first adhesive layer 202 and the first device layer 102, process parameters may be gradually adjusted during the formation of first adhesive layer 202 to gradually change element concentrations in the first adhesive layer 202, so that the material composition of first device layer 102 and first adhesive layer 202 at two sides of the bonding interface would be similar. In an embodiment, the parameters of deposition process are adjusted along with the increase of thickness of the first adhesive layer 202 during the process of forming the first adhesive layer 202, so that the silicon atomic concentration in the first adhesive layer 202 may gradually change along with the increase of thickness of the first adhesive layer 202. In another embodiment, the other element concentrations in the first adhesive layer 202 may also be adjusted depending on the material on the surface of the first device layer 102. For example, the carbon atomic concentration in the first adhesive layer 202 may be uniform, or the carbon atomic concentration may gradually change along with the increase of thickness of first bonding layer. In another embodiment, the parameters of deposition process may remain unchanged during the formation of first adhesive layer 202 so that the element concentrations in different thickness levels of the first adhesive layer 202 may also remain unchanged.

In order to further increase the bonding force between the first adhesive layer 202 and the first bonding layer 201, process parameters may be gradually adjusted during the formation of the first bonding layer 201 to gradually change element concentrations of the first bonding layer 201, so that the material composition of first bonding layer 201 and first adhesive layer 202 at two sides of the bonding interface would be similar. In an embodiment, the parameters of deposition process are adjusted along with the increase of thickness of the first bonding layer 201 during the process of forming the first bonding layer 201, so that the carbon atomic concentration may gradually change along with the increase of thickness of the first bonding layer 201. In another embodiment, the carbon atomic concentration may be gradually decreased or may be gradually increased then gradually decreased along with the increase of thickness of the first bonding layer 201. In another embodiment, the parameters of deposition process may remain unchanged during the formation of first bonding layer 201 so that the element concentrations in different thickness levels of the first bonding layer 201 may remain unchanged.

The thickness of first bonding layer 201 is larger than the thickness of first adhesive layer 202 to ensure that the first bonding layer 201 may provide sufficient bonding thickness when bonding the first bonding layer 201 to other bonding layers. In an embodiment, the thickness of first adhesive layer 202 is larger than 10 Å, and the thickness of first bonding layer 201 is larger than 100 Å.

In another embodiment, the first adhesive/bonding stack 200 may include at least three stacked sub-layers. In an embodiment, the first adhesive/bonding stack 200 includes a first adhesive layer 202 and at least two first bonding layers 201. The materials of different first bonding layers 201 may be the same or different. In another embodiment, the first adhesive/bonding stack 200 may include at least two first adhesive layers 202 and a first bonding layer 201. The first adhesive/bonding stack 200 may include multiple alternatingly stacked first adhesive layer 202 and first bonding layer 201. In the situation that the first adhesive/bonding stack 200 includes at least three sub-layers, the surface of first substrate 100 would contact the first adhesive layer 202 and the surface of first adhesive/bonding stack 200 will be a surface of first bonding layer 201, so that the surfaces of first adhesive/bonding stack 200 and the first device layer may have higher adhesive forces to provide stronger bonding force when bonding the first adhesive/bonding stack 200 to other bonding layers.

In an embodiment, the carbon concentration in the first adhesive/bonding stack 200 would gradually change in a direction of thickness of the first adhesive/bonding stack 200. In another embodiment, the compactness of each layer in the first adhesive/bonding stack 200 would gradually change in a direction of thickness of the first adhesive/bonding stack 200.

Please refer to FIG. 3. In another embodiment, the method further includes providing a second substrate 300 and forming a second adhesive/bonding stack 400 on the surface of second substrate 300.

The second substrate 300 includes a second semiconductor substrate 301 and a second device layer 302 on the surface of second semiconductor substrate 301.

The second adhesive/bonding stack 400 is formed on the surface of second device layer 302 by using CVD process. In the embodiment, the second adhesive/bonding stack 400 includes at least one first bonding layer 401 and at least first adhesive layer 402. Specific material and structure of the second adhesive/bonding stack 400 may refer to the description of first adhesive/bonding stack 200 in the embodiment above. No more redundant description will be herein provided. In an embodiment, the material and structure of second adhesive/bonding stack 400 is identical to the ones of above-described first adhesive/bonding stack 200.

Please refer to FIG. 4. The surfaces of second adhesive/bonding stack 400 and first adhesive/bonding stack 200 are correspondingly bonded and fixed. During the bonding process, the first bonding layer 401 on the surface of second adhesive/bonding stack 400 is bonded to the first bonding layer 201 on the surface of first adhesive/bonding stack 200.

Both of the first bonding layer 401 and the first bonding layer 201 include carbon element, which is partially in the form of —CH3. The —CH3 may be easily oxidized into −OH and may form Si—O bonds in the bonding process, so that more Si—O bonds may be formed on the bonding interface to provide stronger bonding force. In an embodiment, the bonding force between the first bonding layer 401 and the first bonding layer 201 is larger than 2J/m2 , while the bonding force in prior art is usually smaller than 1.5 J/m2 since its bonding layer contain no carbon element.

In an embodiment, the first substrate 100 is a substrate with 3D NAND memory formed thereon, and the second substrate 200 is a substrate with peripheral circuit formed thereon.

In another embodiment, the above-mentioned adhesive/bonding stack may be formed on both sides of a substrate to realize the bonding solution with at least three substrates.

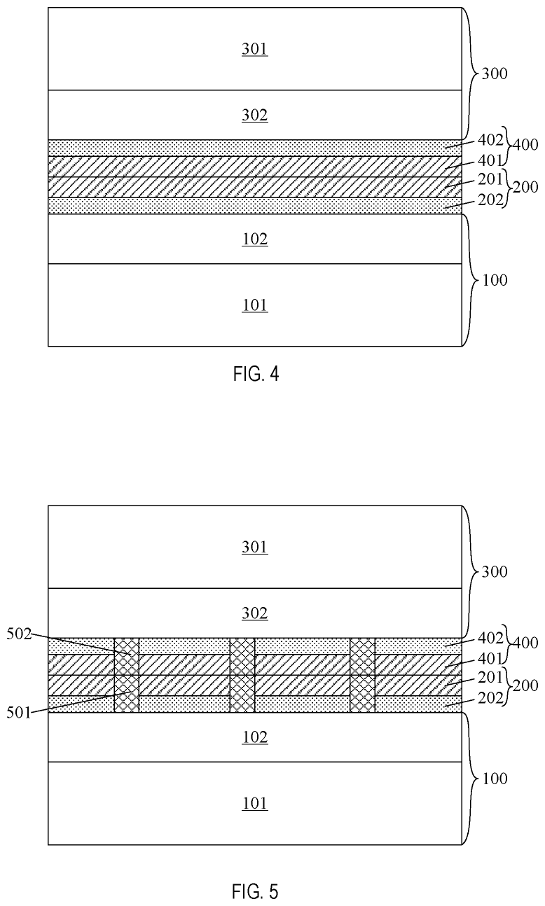

Please refer to FIG. 5. In another embodiment, the method further includes forming a first bonding pad 501 penetrating through the first adhesive/bonding stack 200, forming a second bonding pad 502 penetrating through the second adhesive/bonding stack 400, correspondingly bonding the first bonding pad 501 and the second bonding pad 502 when correspondingly bonding the surface of second adhesive/bonding stack 400 to the surface of first adhesive/bonding stack 200.

The first bonding pad 501 and the second bonding pad 502 may be connected to semiconductor devices and metal interconnections in the first device layer 102 and the second device layer 302, respectively.

The method of forming first bonding pad 501 includes: performing a patterning process to the first adhesive/bonding stack 200 to form openings penetrating through the first adhesive/bonding stack 200, filling the openings with metal material and performing a planarization process to form first bonding pads 501 filling up the openings, using the same method to form the second bonding pad 502 in the second adhesive/bonding stack 400, and bonding the first bonding pad 501 and the second bonding pad 502 to realize the electrical connection between the semiconductor devices in first device layer 102 and second device layer 302.

The materials of first bonding pad 501 and second bonding pad 502 may be metal material like copper (Cu) and tungsten (w), etc. The bonding interface between the first adhesive/bonding stack 200 and the second adhesive/bonding stack 400 is a bonding interface between the first bonding layers 201 and the first bonding layers 401. The carbon element included in the first bonding layers 201 and the first bonding layers 401 may efficiently block and prevent the material diffusion of first bonding pads 501 and second bonding pad 502 at the bonding interface, thereby improving the performance of semiconductor structure.

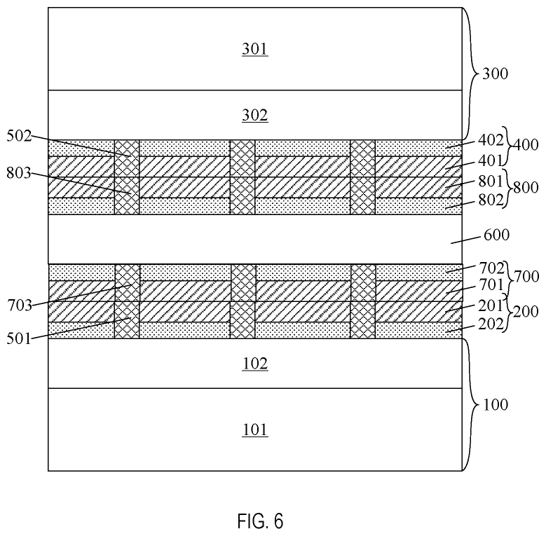

The above-described method may also be used in the bonding of multiple substrates. Please refer to FIG. 6. In an embodiment of present invention, the method further includes:
providing a third substrate 600, forming a third adhesive/bonding stack 700 and a fourth adhesive/bonding stack 800 respectively at two opposite surfaces of the third substrate 600, bonding the surfaces of third adhesive/bonding stack 700 and first adhesive/bonding stack 200, bonding the surfaces of fourth adhesive/bonding stack 800 and second adhesive/bonding stack 400 to form tri-layer bonding structure.

In the embodiment, the third adhesive/bonding stack 700 includes a first adhesive layer 702 and a first bonding layer 701. The fourth adhesive/bonding stack 800 includes a first adhesive layer 802 and a first bonding layer 801. The surfaces of first bonding layer 801 and first bonding layer 401 are bonded together, and the surfaces of first bonding layer 701 and first bonding layer 201 are bonded together.

In another embodiment, the third adhesive/bonding stack 700 and the fourth adhesive/bonding stack 800 may be another structure. The method of forming third adhesive/bonding stack 700 and fourth adhesive/bonding stack 800 may refer to the forming method of first adhesive/bonding stack 200 in the embodiment above. No redundant description will be therein provided.

In the embodiment, the method further includes: forming a third bonding pad 703 in the third adhesive/bonding stack 700, forming a fourth bonding pad 803 in the fourth adhesive/bonding stack 800, bonding the third bonding pad 703 and the first bonding pad 501, and bonding the fourth bonding pad 803 and the second bonding pad 502.

In another embodiment, the above-described method may be used to form a bonding structure with at least four layers.

In the embodiment above, forming a bonding layer with composite structure on the substrate surface may provide higher adhesive force to the substrate surface. The bonding interface therebetween will also have higher bonding force after bonding and may prevent the diffusion of metal materials at the bonding interface, thereby improving the performance of semiconductor structure.

Please note that, in the technical solution of present invention, the type of semiconductor devices in individual substrates of semiconductor structure is not limited to those mentioned in the embodiments. In addition to 3D NAND, it may be complementary metal-oxide-semiconductor (CMOS), CMOS image sensor (CIS) or thin-film transistor (TFT), etc.

The embodiment of present invention further provides a semiconductor structure.

Please refer to FIG. 2, which is a schematic figure of a semiconductor structure in an embodiment of the present invention.

The semiconductor structure may include a first substrate 100 and a first adhesive/bonding stack 200 on the surface of first substrate 100, wherein the first adhesive/bonding stack 200 includes at least one stacked first bonding layer 201 and at least one stacked first adhesive layer 202, and the materials of the first adhesive layer 202 and first bonding layer 201 are different. The material of first bonding layer 201 includes dielectric material like silicon, nitrogen and carbon, and the material of first adhesive layer 202 includes dielectric material like silicon and nitrogen.

The first substrate 100 includes a first semiconductor substrate 101, a first device layer 102 formed on the surface of first semiconductor substrate 101.

The first semiconductor substrate 101 may be single-crystal silicon substrate, germanium (Ge) substrate, silicon-germanium (SiGe) substrate, silicon-on-insulator (SOI) substrate or germanium-on-insulator (GOI) substrate, etc. Suitable first semiconductor substrate 101 may be selected depending on actual requirement of the device, but not limited thereto. In preferred embodiment, the first semiconductor substrate 101 is a single-crystal silicon wafer.

The first device layer 102 includes semiconductor devices formed on first semiconductor substrate 101, metal interconnections connecting the semiconductor devices, dielectric layers covering the semiconductor devices and the metal interconnections, etc. The first device layer 102 may be multilayer or single-layer structure. In an embodiment, the first device layer 102 includes dielectric layers and 3D NAND structure formed in the dielectric layers.

The first adhesive/bonding stack 200 includes a first bonding layer 201 on the surface of first substrate 100 and a first adhesive layer 202 on the surface of first bonding layer 201. The materials of first bonding layer 201 and first adhesive layer 202 may be different. More specifically, the first bonding layer 201 and first adhesive layer 202 may include the same elements, but with different element concentrations, or the first bonding layer 201 and first adhesive layer 202 may include different elements.

The material of first bonding layer 201 includes the dielectric materials like silicon (Si), nitrogen (N) and carbon (C). The material of first adhesive layer 202 includes the dielectric materials like silicon (Si) and nitrogen (N). The first bonding layer 201 and the first bonding layer 202 may be further doped with at least one element of oxygen (O), hydrogen (H), phosphorus (P) and fluorine (F), depending on the reagent gas using in the PECVD process and the requirement of products. For example, the material of first bonding layer 201 may be doped silicon nitride, doped silicon oxynitride and doped silicon carbonitride, etc. The material of first adhesive layer 202 may be silicon nitride and silicon oxynitride, etc.

The element concentration in the first bonding layer 201 and the first adhesive layer 202 may be adjusted by controlling the process parameters of forming the first bonding layer 201 and the first adhesive layer 202, so that the adhesive force between material layers and the dielectric constant of first adhesive/bonding stack 200 may, therefore, be adjusted.

The first bonding layer 201 is on the top of first adhesive/bonding stack 200. The carbon in first bonding layer 201 may efficiently increase the bonding force between the first bonding layer 201 and another bonding layer in bonding process. The higher the carbon concentration, the stronger the bonding force to other bonding layers in the bonding process. In an embodiment, the atomic concentration of carbon in the first bonding layer 201 is larger than 0% and smaller than 50%.

The first adhesive layer 202 has higher silicon atomic concentration, thereby increasing the compactness of first adhesive layer 202 and the bonding force to the first bonding layer 201 and the first device layer 102. In an embodiment, the silicon atomic concentration in the first adhesive layer 202 is larger than 20%, and its carbon atomic concentration is smaller than the carbon atomic concentration in the first bonding layer 201. In comparison to the method that forming the first bonding layer 202 directly on the surface of first device layer 102, the adhesive force between the first adhesive/bonding stack 200 and the first device layer 102 in the embodiment may be effectively improved since the adhesive force between the first adhesive layer 202 and the first device layer 102 is stronger.

Since the bonding force between different materials is related to material compositions at both sides of the bonding interface, the bonding force would get stronger if the material compositions are similar. In order to further increase the adhesive force between the first adhesive layer 202 and the first device layer 102, the element concentrations in the first adhesive layer 202 would gradually change along with the thickness of first adhesive layer 202, so that the material composition of first device layer 102 and the material at two sides of the first adhesive layer 202 would be similar. In an embodiment, the silicon atomic concentration in the first adhesive layer 202 may gradually change along with the increase of thickness of the first adhesive layer 202. In another embodiment, the other element concentrations in the first adhesive layer 202 may also be changed depending on the material on the surface of the first device layer 102. In another embodiment, the element concentrations in different thickness levels of the first adhesive layer 202 may remain unchanged to provide uniform atomic concentration.

In order to further increase the adhesive force between the first adhesive layer 202 and the first bonding layer 201, the element concentrations of the first bonding layer 201 may gradually change along with the thickness, so that the material composition of first bonding layer 201 and the materials at two sides of the first adhesive layer 202 would be similar. In an embodiment, the carbon atomic concentration in the first bonding layer 201 may be gradually increased along with the increase of thickness of the first bonding layer 201. In another embodiment, the carbon atomic concentration in the first bonding layer 201 may be gradually decreased or may be gradually increased then gradually decreased along with the increase of thickness of the first bonding layer 201. In another embodiment, the element concentrations in different thickness levels of the first bonding layer 201 may remain unchanged to provide uniform atomic concentration.

The thickness of first bonding layer 201 is larger than the thickness of first adhesive layer 202 to ensure that the first bonding layer 201 may provide sufficient bonding thickness when bonding the first bonding layer 201 to other bonding layers. In an embodiment, the thickness of first adhesive layer 202 is larger than 10 Å, and the thickness of first bonding layer 201 is larger than 100 Å.

In another embodiment, the first adhesive/bonding stack 200 may include at least three sub-layers. In an embodiment, the first adhesive/bonding stack 200 includes a first adhesive layer 202 and at least two first bonding layers 201. The materials of different first bonding layers 201 may be the same or different. In another embodiment, the first adhesive/bonding stack 200 may include at least two first adhesive layers 202 and a first bonding layer 201. The first adhesive/bonding stack 200 may include multiple alternatingly stacked first adhesive layer 202 and first bonding layer 201. In the situation that the first adhesive/bonding stack 200 includes at least three sub-layers, the surface of first substrate 100 would contact the first adhesive layer 202, and the surface of first adhesive/bonding stack 200 will be a surface of first bonding layer 201, so that the surfaces of first adhesive/bonding stack 200 and the first device layer 102 may have higher adhesive forces to generate stronger bonding force when the first adhesive/bonding stack 200 is bonded to other bonding layers.

In an embodiment, the carbon concentration in the first adhesive/bonding stack 200 would gradually change in a direction of thickness of the first adhesive/bonding stack 200. In another embodiment, the compactness of each layer in the first adhesive/bonding stack 200 would gradually change in a direction of thickness of the first adhesive/bonding stack 200.

Please refer to FIG. 4, which is a schematic figure of a semiconductor structure in accordance with another embodiment of the present invention.

In the embodiment, the semiconductor structure further includes a second substrate 300, wherein a second adhesive/bonding stack 400 is formed on the surface of second substrate 300. The surfaces of second adhesive/bonding stack 400 and first adhesive/bonding stack 200 are correspondingly bonded and fixed.

The second substrate 300 includes a second semiconductor substrate 301 and a second device layer 302 on the surface of second semiconductor substrate 301. In the embodiment, the second adhesive/bonding stack 400 includes at least one first bonding layer 401 and at least one first adhesive layer 402. Specific material and structure of second adhesive/bonding stack 400 may refer to the description of first adhesive/bonding stack 200 in the embodiment above. No more redundant description will be herein provided. In an embodiment, the material and structure of second adhesive/bonding stack 400 are identical to the ones of above-mentioned first adhesive/bonding stack 200.

The first bonding layer 401 on the top of second adhesive/bonding stack 400 would be bonded to the surface of first bonding layer 201 on the top of first adhesive/bonding stack 200. Both of the first bonding layer 401 and the first bonding layer 201 include carbon element, which is partially in the form of —CH3. The —CH3 may be easily oxidized into-OH and may form Si—O bonds in the bonding process, so that more Si—O bonds may be formed in the bonding interface to provide stronger bonding force.

In another embodiment, the semiconductor structure may include at least three substrates, wherein adjacent substrates are all bonded together by using the composite bonding layer in the embodiment of present invention.

Please refer to FIG. 5, which is a schematic figure of a semiconductor structure in accordance with another embodiment of the present invention.

In the embodiment, the semiconductor structure further includes a first bonding pad 501 penetrating through the first adhesive/bonding stack 200, a second bonding pad 502 penetrating through the second adhesive/bonding stack 400, wherein the surface of second adhesive/bonding stack 400 and the surface of first adhesive/bonding stack 200 are correspondingly bonded and fixed together, and the first bonding pad 501 and the second bonding pad 502 are also correspondingly bonded and connected together.

The first bonding pad 501 and the second bonding pad 502 may be connected to semiconductor devices and metal interconnections in the first device layer 102 and the second device layer 302, respectively.

The materials of first bonding pad 501 and second bonding pad 502 may be metal material like copper (Cu) and tungsten (w), etc. The bonding interface between the first adhesive/bonding stack 200 and the second adhesive/bonding stack 400 is a bonding interface between the first bonding layers 201 and the first bonding layers 401. The carbon element included in the first bonding layers 201 and the first bonding layers 401 may efficiently block and prevent the material diffusion of first bonding pads 501 and second bonding pad 502 at the bonding interface, thereby improving the performance of semiconductor structure.

In an embodiment, the first substrate 100 is a substrate with 3D NAND memory formed thereon, and the second substrate 200 is a substrate with peripheral circuit formed thereon.

Please refer to FIG. 6, which is a schematic figure of a semiconductor structure in accordance with another embodiment of the present invention.

In the embodiment, the semiconductor structure further includes a third substrate 600. A third adhesive/bonding stack 700 and a fourth adhesive/bonding stack 800 are formed respectively at two opposite surfaces of the third substrate 600, wherein the surfaces of third adhesive/bonding stack 700 and first adhesive/bonding stack 200 are correspondingly bonded and fixed together, and the surfaces of fourth adhesive/bonding stack 800 and second adhesive/bonding stack 400 are bonded and fixed together, to constitute a tri-layer bonding structure.

In the embodiment, the third adhesive/bonding stack 700 includes a first adhesive layer 702 and a first bonding layer 701. The fourth adhesive/bonding stack 800 includes a first adhesive layer 802 and a first bonding layer 801. The surfaces of first bonding layer 801 and first bonding layer 401 are bonded and fixed together, and the surfaces of first bonding layer 701 and first bonding layer 201 are bonded and fixed together.

In another embodiment, the third adhesive/bonding stack 700 and the fourth adhesive/bonding stack 800 may be another structure. The material and structure of third adhesive/bonding stack 700 and fourth adhesive/bonding stack 800 may refer to the ones of first adhesive/bonding stack 200 in the embodiment above. No redundant description will be therein provided.

In the embodiment, a third bonding pad 703 is further formed in the third adhesive/bonding stack 700, and a fourth bonding pad 803 is further formed in the fourth adhesive/bonding stack 800, wherein the third bonding pad 703 and the first bonding pad 501 are bonded together, and the fourth bonding pad 803 and the second bonding pad 502 are bonded together.

In another embodiment, the above-described method may be used to form a bonding structure with at least four layers.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a first device layer;
a first bonding layer disposed on the first device layer;
a second device layer; and
a second bonding layer disposed on the second device layer and located between the second device layer and the first bonding layer,
wherein the first bonding layer is bonded to the second bonding layer, and wherein at least one of the first and second bonding layers comprises dielectric material comprising silicon, nitrogen, and carbon.

2. The semiconductor structure of claim 1, wherein a bonding interface of the first bonding layer and the second bonding layer comprises Si—O bonds.

3. The semiconductor structure of claim 1, wherein an atomic concentration of carbon in the first bonding layer is greater than 0% and less than 50%.

4. The semiconductor structure of claim 1, wherein the first bonding layer comprises a first side adjacent to the first device layer and a second side opposite to the first side, and an atomic concentration of carbon at the second side of the first bonding layer is different from an atomic concentration of carbon at the first side of the first bonding layer.

5. The semiconductor structure of claim 1, wherein an atomic concentration of carbon in the first bonding layer increases along with the increase of thickness of the first bonding layer.

6. The semiconductor structure of claim 1, further comprising:
a first adhesive layer disposed on the first device layer and located between the first device layer and the first bonding layer; and
a second adhesive layer disposed on the second device layer and located between the second device layer and the second bonding layer,
wherein the first and second adhesive layers comprise the dielectric material including the silicon.

7. The semiconductor structure of claim 6, further comprising:
a first bonding pad extending through the first bonding layer and the first adhesive layer; and
a second bonding pad extending through the second bonding layer and the second adhesive layer, wherein the first bonding pad is bonded to the second bonding pad.

8. A semiconductor structure, comprising:
a first device layer;
a first bonding layer disposed on the first device layer;
a first bonding pad extending through the first bonding layer and connected to the first device layer;
a second device layer;
a second bonding layer disposed on the second device layer and located between the second device layer and the first bonding layer; and
a second bonding pad extending through the second bonding layer and connected to the second device layer,
wherein:
the first bonding layer is bonded to the second bonding layer,
the first bonding pad is bonded to the second bonding pad, and
at least one of the first and second bonding layers comprises dielectric material comprising silicon, nitrogen, and carbon.

9. The semiconductor structure of claim 8, wherein a bonding interface of the first bonding layer and the second bonding layer comprises Si—O bonds.

10. The semiconductor structure of claim 8, wherein an atomic concentration of carbon in the first bonding layer is greater than 0% and less than 50%.

11. The semiconductor structure of claim 8, wherein the first bonding layer comprises a first side adjacent to the first device layer and a second side opposite to the first side, and an atomic concentration of carbon at the second side of the first bonding layer is different from an atomic concentration of carbon at the first side of the first bonding layer.

12. The semiconductor structure of claim 8, wherein an atomic concentration of carbon in the first bonding layer increases along with the increase of thickness of the first bonding layer.

13. The semiconductor structure of claim 8, further comprising:
a first adhesive layer disposed on the first device layer and located between the first device layer and the first bonding layer; and
a second adhesive layer disposed on the second device layer and located between the second device layer and the second bonding layer.

14. The semiconductor structure of claim 13, wherein a material of the first adhesive layer comprises the dielectric material including the silicon.

15. The semiconductor structure of claim 14, wherein the first adhesive layer further comprises nitrogen and carbon, and an atomic concentration of carbon in the first adhesive layer is less than an atomic concentration of carbon in the first bonding layer.

16. The semiconductor structure of claim 14, wherein an atomic concentration of silicon in the first adhesive layer is greater than 20%.

17. The semiconductor structure of claim 8, wherein the first bonding pad and the second bonding pad comprise a metal material.

18. The semiconductor structure of claim 8, wherein the first device layer comprises a three-dimensional NAND structure, and the second device layer comprises a peripheral circuit.

19. A method of forming a semiconductor structure, comprising:
providing a first semiconductor substrate and a first device layer on the first semiconductor substrate;
forming a first bonding layer on the first device layer;
providing a second semiconductor substrate and a second device layer on the second semiconductor substrate;
forming a second bonding layer on the second device layer; and
bonding the first bonding layer to the second bonding layer, wherein at least one of the first and second bonding layers comprises dielectric material comprising silicon, nitrogen, and carbon.

20. The method of claim 19, further comprising:
forming a first bonding pad extending through the first bonding layer;
forming a second bonding pad extending through the second bonding layer; and
bonding the first bonding pad to the second bonding pad.
